(19) United States
(12) Patent Application Publication
(10) Pub. No.: US 2008/0111593 A1
(43) Pub. Date: May 15, 2008

(54) Power-up reset circuits and semiconductor devices including the same

(75) Inventors: Sung-Yub Jang, Hwaseong-si (KR); Hi-Choon Lee, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/819,608

(22) Filed: Jun. 28, 2007

(30) Foreign Application Priority Data
Nov. 15, 2006 (KR) 10-2006-0112848

(51) Int. Cl. H03K 3/00; H03L 7/00

(52) U.S. Cl. 327/143; 327/198; 327/530

(57) ABSTRACT

A power-up reset circuit includes a sensing circuit and an output circuit. The sensing circuit outputs a node voltage in response to an external power supply voltage. The output circuit outputs a voltage sensing signal in response to the node voltage. A signal generation circuit outputs a reset signal in response to the voltage sensing signal. A first resistance adjustment circuit adjusts the level of the node voltage in response to an externally input first control signal. A second resistance adjustment circuit adjusts the level of the voltage sensing signal in response to an externally input second control signal.

### PRIORITY STATEMENT

This non-provisional patent application claims priority under 35 U.S.C. § 119 to Korean Patent Application No. 2006-0112848, filed on Nov. 15, 2006, in the Korean Intellectual Property Office (KIPO), the entire contents of which are incorporated herein by reference.

### BACKGROUND

### Description of the Conventional Art

Externally applying a power supply voltage for starting up a conventional semiconductor device is referred to as power-up. The externally applied power supply voltage may be only partially stabilized during a power-up operation, and thus, determining a logic high level or a logic low level of data or various signals used in the semiconductor device may be relatively difficult.

Conventional semiconductor devices may also be initialized when the power supply voltage is applied for the first time. To suppress operation of and initialize the semiconductor device during power-up, conventional semiconductor devices may include a power-up reset circuit.

FIG. 1 illustrates a conventional power-up reset circuit including a sensing unit 10, an output unit 20, a signal generation unit 30, a capacitor C1 and a transistor N2. The sensing unit 10 may include resistors R1 to R4, fuses F1 and F2. The output unit 20 may include a resistor R5, a fuse F3 and an N-type Metal Oxide Semiconductor (NMOS) transistor N1. The signal generation unit 30 may include inverters I1 to I3.

The sensing unit 10 may output a node voltage VA in response to an externally applied power supply voltage Vext. For example, the node voltage VA of a node A in the sensing unit 10 may have a value corresponding to the external power supply voltage Vext divided by the resistors R1 to R4. Accordingly, the node voltage VA may be proportional to the level of the external power supply voltage Vext. The output unit 20 may output a voltage sensing signal VD in response to the node voltage VA. In one example, the NMOS transistor N1 may be deactivated or turned off when the node voltage VA is less than or equal to a reset voltage level and the output unit 20 may output the voltage sensing signal VD having a logic high level.

In another example, the NMOS transistor N1 may be activated or turned on when the node voltage VA is greater than the reset voltage level and the output unit 20 may output the voltage sensing signal VD having a logic low level. The reset voltage level may depend on values of the resistors R1 to R4. If the reset voltage level is different from a desired level, fuses F1, F2 and F3 may be used to adjust the reset voltage level. For example, a portion of the connected fuses F1, F2 and F3 may be cut to increase the resistance between the node A and the terminal at which the external power supply voltage Vext is applied, between the node A and the ground voltage or between the terminal at which the external power supply voltage Vext is applied and a node where the voltage sensing signal VD is output.

Still referring to FIG. 1, the signal generation unit 30 may invert the voltage sensing signal VD and delay the voltage sensing signal by a first time period to output a reset signal VCCH. The capacitor C1 may suppress noise. For example, the capacitor C1 may serve as a low-pass filter suppressing relatively high frequency components from the voltage sensing signal VD. The transistor N2 may serve as a diode, and may operate at a relatively high speed. For example, when the node B has a negative voltage, the transistor N2 may change the negative voltage to a ground voltage level to allow faster operations to be performed.

FIG. 2 is a graph illustrating changes in reset signal VCCH according to the external power supply voltage Vext of the power-up reset circuit of the conventional semiconductor memory device shown in FIG. 1. Referring to FIG. 2, a dotted line denotes the externally applied power supply voltage Vext, and a solid line denotes the reset signal VCCH.

The external power supply voltage Vext may gradually increase during a power-up operation so that the node voltage VA also increases. When the external power supply voltage Vext increases to a reset voltage level VL (e.g., at time T1), the reset signal VCCH may transition from a logic low level to the external power supply voltage Vext level (e.g., a logic high level), and the semiconductor device may enter a normal operating state. As described above, the reset voltage level VL may be determined by the resistance of the sensing unit 10 or the resistance of the output unit 20.

As described above, the reset voltage level VL may have a value different from a desired value and the semiconductor device may not operate properly without adjustment to the reset voltage level VL. For example, when the reset voltage level VL has a value lower than the desired value, a sufficient voltage may not be supplied to the semiconductor device, and the semiconductor device may not operate in a normal state. When the reset voltage level VL has a value higher than the desired value, the reset signal VCCH may transition later than time T1, which may cause operation timing problems. Such timing problems may occur in the same or substantially the same manner even when the semiconductor device having the power-up reset circuit is under test, so that tests may not be performed without adjustment to the reset voltage level VL.

According to the conventional art, fuses F1, F2 and F3 may be cut even during testing to adjust the reset voltage level VL as described above with reference to FIG. 1. However, adjusting the reset voltage level VL using the fuses F1, F2 and F3 may delay testing.

### SUMMARY

Example embodiments relate to power-up reset circuits, for example, power-up reset circuits capable of adjusting a reset voltage level without cutting fuses during testing and semiconductor devices including the same.

At least one example embodiment provides a power-up reset circuit capable of adjusting a reset voltage level more simply using pads during testing. At least one other example embodiment provides a semiconductor device including a power-up reset circuit.

According to at least one example embodiment, a power-up reset circuit may include a sensing circuit, an output circuit, a signal generation circuit, a first resistance adjustment circuit and/or a second resistance adjustment circuit. The sensing circuit may be configured to output a node voltage in response to an external power supply voltage. The output circuit may be configured to output a voltage sensing signal in response to the node voltage. The signal generation circuit may be configured to output a reset signal in response to the voltage sensing signal. The first resistance adjustment circuit may be configured to adjust the level of the node voltage in response to an externally input first control signal, and the second resistance adjustment circuit may be configured to adjust the level of the voltage sensing signal in response to an externally input second control signal.

At least one other example embodiment provides a power-up reset circuit. According to this example embodiment, a power-up reset circuit may include a sensing circuit, a first resistance adjustment circuit, a second resistance adjustment circuit, an output circuit and/or and a signal generation circuit. The sensing circuit may include a plurality of first resistors serially connected between an external power supply voltage and an output terminal where a node voltage is output, and a plurality of second resistors serially connected between the output terminal and a ground voltage. The first resistance adjustment circuit may include a PMOS transistor connected to at least a portion of the first resistors in parallel. The externally input first control signal may be applied to a gate of the PMOS transistor. The second resistance adjustment circuit may include a PMOS transistor connected to at least a portion of the second resistors in parallel. The externally input second control signal may be applied to a gate of the PMOS transistor. The output circuit may include a pull-up circuit and a pull-down circuit. The pull-down circuit may be connected between the pull-up circuit and the ground voltage and may include an NMOS transistor where the node voltage is applied. The pull-down circuit may output a voltage sensing signal in response to the node voltage. The signal generation circuit may output a reset signal in response to the voltage sensing signal.

At least one other example embodiment provides a power-up reset circuit. According to at least this example embodiment, a sensing circuit may be configured to output a node voltage in response to an external power supply voltage. An output circuit may be configured to output a voltage sensing signal in response to the node voltage. A signal generation circuit may be configured to output a reset signal in response to the voltage sensing signal. At least one first resistance adjustment circuit may be configured to adjust a level of the node voltage in response to an externally input first control signal.

At least one other example embodiment is directed to a semiconductor device. According to at least this example embodiment, a semiconductor device may include a plurality of pads for externally inputting a plurality of test signals and a power-up reset circuit. The power-up reset circuit may include may include a sensing circuit, an output circuit, a signal generation circuit, a first resistance adjustment circuit and/or a second resistance adjustment circuit. The sensing circuit may be configured to output a node voltage in response to an external power supply voltage. The output circuit may be configured to output a voltage sensing signal in response to the node voltage. The signal generation circuit may be configured to output a reset signal in response to the voltage sensing signal. The first resistance adjustment circuit may be configured to adjust the level of the node voltage in response to a first test signal among the plurality of test signals, and the second resistance adjustment circuit may be configured to adjust the level of the voltage sensing signal in response to a second test signal among the plurality of test signals.

According to at least some example embodiments, the sensing circuit may include a plurality of first resistors serially connected between the external power supply voltage and an output terminal where the node voltage is output, and a plurality of second resistors serially connected between the output terminal and a ground voltage. The first resistance adjustment circuit may include a first resistance adjustment transistor (e.g., a P-type Metal Oxide Semiconductor (PMOS) transistor) connected to at least a portion of the first resistors in parallel. The first test signal may be applied to a gate of the first resistance adjustment transistor.

According to at least some example embodiments, the output circuit may include a pull-up circuit including a plurality of third resistors, and a pull-down circuit. The second resistance adjustment circuit may include a second resistance adjustment transistor (e.g., a PMOS transistor) connected to at least a portion of the third resistors in parallel. The second test signal may be applied to a gate of the second resistance adjustment transistor.

According to at least some example embodiments, the signal generation circuit may include at least one inverter. The inverter may invert the voltage sensing signal, delay the voltage sensing signal by a first time period, and output the reset signal. The signal generation circuit may further include a latch configured to maintain the reset signal at a high logic level after the reset signal transitions to the high logic level.

According to at least some example embodiments, the signal generation circuit may include at least one inverter and/or a latch configured to maintain the reset signal at a logic high level after the reset signal transitions to the logic high level.

### BRIEF DESCRIPTION OF THE DRAWINGS

The present invention will be apparent from the description of example embodiments, as illustrated in the accompanying drawing. The drawings are not necessarily to scale, emphasis instead being placed upon illustrating principles.

FIG. 1 is a block diagram of a conventional power-up reset circuit;

FIG. 2 is a graph illustrating changes in reset signal according to an external power supply voltage in the power-up reset circuit of FIG. 1;

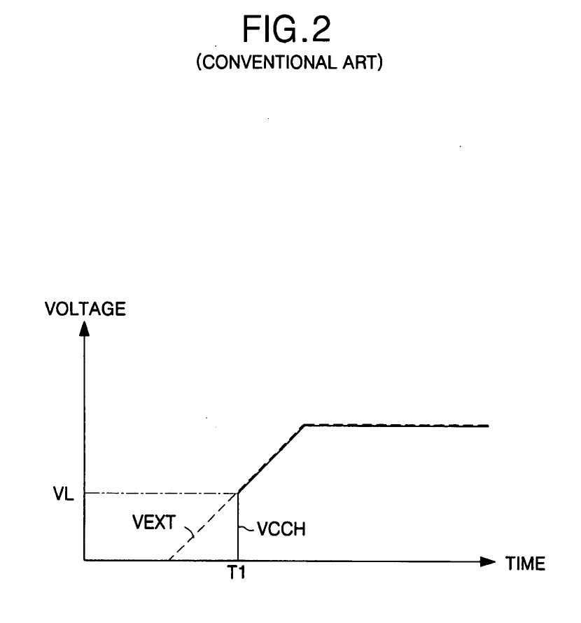

FIG. 3 is a block diagram of a power-up reset circuit according to an example embodiment;

FIG. 4 is a block diagram of a power-up reset circuit according to another example embodiment;

FIG. 5 is a block diagram of a power-up reset circuit according to another example embodiment; and

FIG. 6 is a block diagram of a semiconductor device including a power-up reset circuit according to an example embodiment;

### DETAILED DESCRIPTION OF EXAMPLE EMBODIMENTS

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved. Power-up reset circuit and/or semiconductor devices including the same will be described hereinafter with reference to the accompanying drawings.

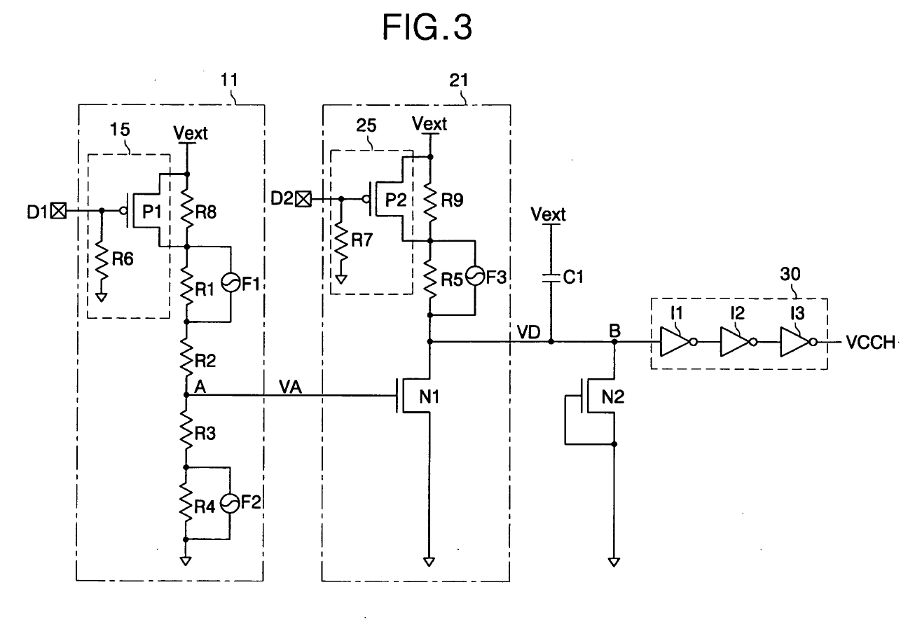

FIG. 3 is a block diagram of a power-up reset circuit according to an example embodiment. The power-up reset circuit of FIG. 3 may include a sensing circuit or unit 11, an output circuit or unit 21, a signal generation circuit or unit 30, a storage device (e.g., a capacitor, capacitor circuit or the like) C1 and/or a switching device (e.g., a transistor, a transistor circuit or the like) N2. The sensing circuit 11 may include a first resistance adjustment circuit or unit 15, a plurality of first resistors R1, R2 and R8, a plurality of second resistors R3 and R4 and a plurality of fuses F1 and F2. The plurality of first resistors R1, R2 and R8 may be connected between a terminal at which an external power supply voltage is applied and a node A outputting a node voltage VA. The plurality of second resistors R3 and R4 may be connected between the node A and a ground voltage.

The output circuit 21 may include a second resistance adjustment circuit 25, a plurality of third resistors R5 and R9, a transistor (e.g., an NMOS transistor) N1, and a fuse F3. The signal generation circuit 30 may include a plurality of inverters I1, I2 and I3. The first and second resistance adjustment circuits 15 and 25 may include resistors R6 and R7 and transistors (e.g., PMOS transistors) P1 and P2, respectively. The transistors P1 and P2 may be connected in parallel with resistors R8 and R9, respectively, and may have gates receiving signals applied from pads D1 and D2. Referring to FIG. 3, reference symbols “D1” and “D2” denote pads through which signals may be externally applied. The signal generation circuit 30 may include, for example, three inverters I1 to I3; however, the number of inverters may be any odd number.

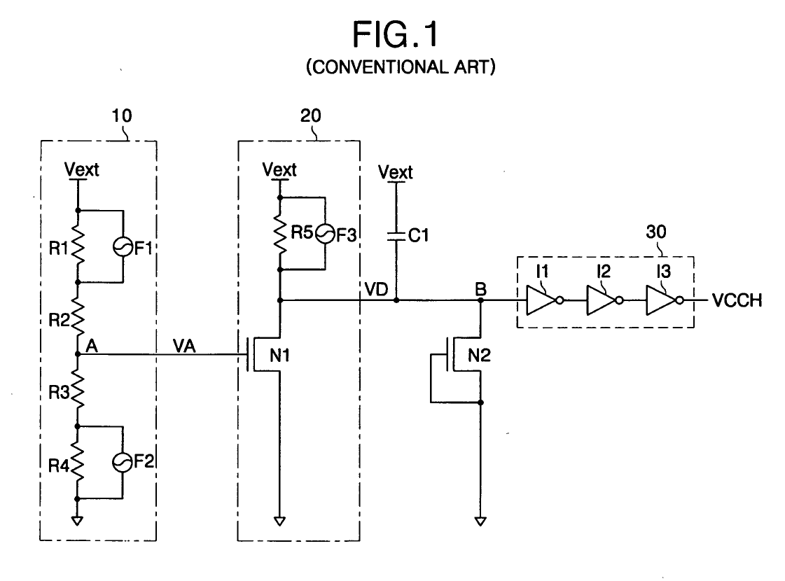

Functions of the circuit blocks shown in FIG. 3 may be similar or substantially similar to those shown in FIG. 1. For example, the sensing circuit 11 may output a node voltage VA in response to the externally applied power supply voltage Vext using the first resistors R1, R2 and R8 and the second resistors R3 and R4. The node voltage VA may be proportional to the level of the external power supply voltage Vext.

The first resistance adjustment circuit 15 may vary the resistance in response to a signal input through the pad D1. For example, when a signal having a logic high level is input through the pad D1, the transistor P1 may be deactivated or turned off so that the resistance between the terminal where the external power supply voltage Vext is applied and the node A increases. A signal having a logic high level may be applied to the pad D1 when a reset voltage level is less than a desired value. Accordingly, the resistance between the terminal where the external power supply voltage Vext may be applied and the node A may increase, thereby decreasing the node voltage VA of the node A. In this example, the transistor N1 may be activated when a voltage level of the external power supply voltage Vext is increased higher than the voltage level of the external power supply voltage Vext when the PMOS transistor P1 is turned, such that the reset signal VCCH transitions to a logic high level when the external power supply voltage Vext having the higher level is applied. For example, the reset voltage level may increase.

The output circuit 21 may output a voltage sensing signal VD in response to the node voltage VA. For example, the output circuit 21 may output the voltage sensing signal VD having a logic high level when the node voltage VA has a level less than a desired reset voltage level, and may output the voltage sensing signal VD having a logic low level when the node voltage VA has a level greater than the desired reset voltage level. The third resistors R5 and R9 of the output circuit 21 act as a pull-up circuit, and the transistor N1 may serve as a pull-down circuit. The second resistance adjustment unit 25 may vary the resistance in response to a signal input through the pad D2. For example, the transistor P2 may be deactivated or turned off when a signal having a logic high level is input through the pad D2, so that the resistance between a terminal where the external power supply voltage Vext is applied and a node where the voltage sensing signal VD is output increases. The signal having a logic high level may be applied to the pad D2 when the reset voltage level is higher than a desired value. The resistance between the terminal where the external power supply voltage Vext may be applied and the node where the voltage sensing signal VD may be output increases, so that the voltage of the node B (e.g., the voltage of the sensing signal VD) decreases. In this example, the output signal of the inverter I1 may transition to a logic high level even when the external power supply voltage Vext having a level lower than the case in which the transistor P2 is turned on is applied, so that the reset signal VCCH may transition to a logic high level even when the external power supply voltage having the lower level is applied. For example, the reset voltage level may decrease.

The signal generation circuit 30 may invert the voltage sensing signal VD, and may delay the voltage sensing signal VD by a first time period to output the reset signal VCCH. The capacitor C1 and the transistor N2 may perform the same or substantially the same functions as those described above with reference to FIG. 1.

For example, the power-up reset circuit shown in FIG. 3 may adjust resistances of the sensing circuit 11 and/or resistances of the output circuit 21 by applying an appropriate signal to the first resistance adjustment circuit 15 and/or the second resistance adjustment circuit 25 through the pad D1 or D2 to adjust the reset voltage level, so that the fuses F1, F2 and F3 need not be cut to adjust the reset voltage level during testing. One or more of the fuses F1, F2 and/or F3 may be cut during or after completing the test to obtain the same or substantially the same reset voltage level.

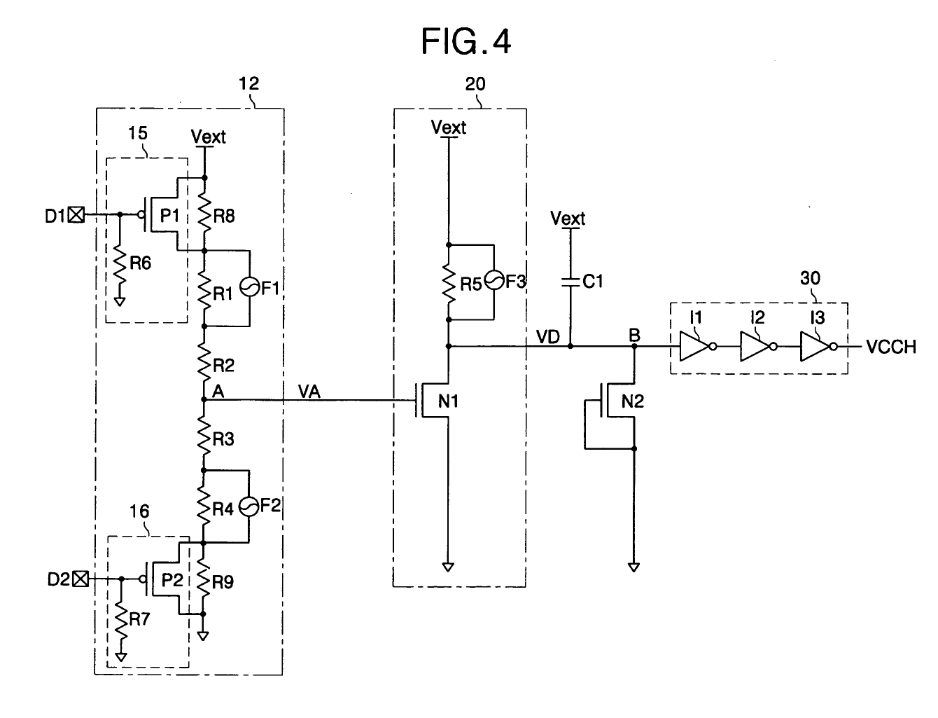

FIG. 4 is a block diagram of a power-up reset circuit according to another example embodiment. The power-up reset circuit of FIG. 4 may include a sensing circuit or unit 12, an output circuit or unit 20, a signal generation circuit or unit 30, a storage device (e.g., a capacitor, capacitor circuit or the like) C1 and/or a switching device (e.g., (e.g., a transistor, transistor circuit or the like) N2. The sensing circuit 12 may include a plurality of first and second resistance adjustment circuits 15 and 16, a plurality of first resistors R1, R2 and R8 connected between a terminal at which an external power supply voltage Vext may be applied and a node A at which a node voltage VA may be output, a plurality of second resistors R3, R4 and R9 connected between the node A and a ground voltage, and a plurality of fuses F1 and F2. The output circuit 20 may include a resistor R5, a fuse F3 and/or a transistor (e.g., an NMOS transistor) N1. The signal generation circuit 30 may include a plurality of inverters I1, I2 and I3. The first and second resistance adjustment circuits 15 and 16 may include resistors R6 and R7 and transistors (e.g., PMOS transistors) P1 and P2, respectively. The transistors P1 and P2 may be respectively connected to the resistors R8 and R9 in parallel. Gates of the transistors P1 and P2 may receive signals applied from the pads D1 and D2, respectively.

Still referring to FIG. 4, the sensing circuit 12 may output the node voltage VA in response to the external power supply voltage Vext. The first resistance adjustment circuit 15 and the second resistance adjustment circuit 16 may adjust resistances in response to signals input from the pads D1 and D2, respectively. For example, the node voltage VA may have a value proportional to the external power supply voltage Vext as determined by the resistors. A signal having a logic high level may be applied through the pad D1 when a reset voltage level has a value lower than a desired (e.g., a design) value. Accordingly, the transistor P1 may be deactivated or turned off, so that the resistance between the terminal to which the external power supply voltage Vext is applied and the node A may increase, thereby decreasing the node voltage VA of the node A.

The transistor N1 may be activated or turned on when the external power supply voltage Vext having a higher value is applied, so that the reset voltage level may increase. A signal having a logic high level may be applied when the reset voltage level has a value higher than a desired or design value. The transistor P2 may be deactivated or turned off, so that the resistance between the node A and the ground voltage may increase, thereby increasing the node voltage VA of the node A. Accordingly, the transistor N1 may be activated or turned on even when the external power supply voltage Vext having a lower value is applied, so that the reset voltage level may decrease.

Functions of the output circuit 20, the signal generation circuit 30, the storage device C1 and the switching device N2 may be the same or substantially the same as described above with regard to FIG. 1. Thus, a detailed discussion will be omitted for the sake of brevity.

Power-up reset circuits as shown in FIG. 4 may adjust resistances of the sensing circuit 12 by applying signals to the pads D1 and D2 so that the reset voltage level may be adjusted. Therefore, fuses F1, F2 and F3 need not be cut to adjust the reset voltage level during testing.

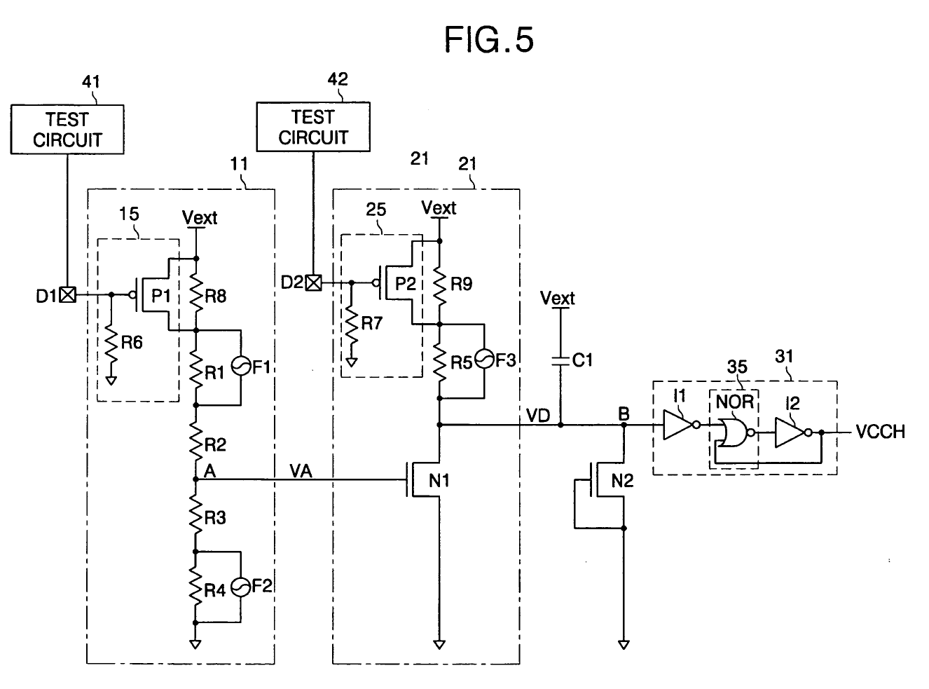

FIG. 5 is a block diagram of a power-up reset circuit according to another example embodiment. The power-up reset circuit of FIG. 5 may include a sensing circuit 11, an output circuit 21, a signal generation circuit 31, a storage device (e.g., a capacitor, capacitor circuit or the like) C1 and/or a switching device (e.g., (e.g., a transistor, transistor circuit or the like) N2. The sensing circuit 11 may include a first resistance adjustment circuit 15, a plurality of first resistors R1, R2 and R8 connected between a terminal at which an external power supply voltage Vext is applied and a node A at which a node voltage VA is output, a plurality of second resistors R3 and R4 connected between the node A and a ground voltage, fuses F1 and F2. The output circuit 21 may include a second resistance adjustment circuit 16, a plurality of resistors R5 and R9, a fuse F3 and a transistor (e.g., an NMOS transistor) N1. The signal generation circuit 31 may include a plurality of inverters I1 and I2 and a latch 35 having a logic (e.g., a NOR) gate.

Referring to FIG. 5, a plurality of test circuits 41 and 42 may generate various signals for testing in response to signals input from the pads D1 and D2, respectively.

The sensing circuit 11, the output circuit 21, the storage device C1 and/or the switching device N2 may function in the same or substantially the same manner as those described above with reference to FIGS. 1 and/or 3, and thus, a detailed discussion will be omitted for the sake of brevity. The signal generation circuit 31 may invert a voltage sensing signal VD input from the output circuit 21, and may delay the voltage sensing signal by a first time period to generate a reset signal VCCH. The latch 35 may maintain a logic high level after the reset signal VCCH transitions to the logic high level.

In conventional semiconductor devices, adding pads may be relatively difficult due to, for example, spatial limitations. As a result, a power-up reset circuit may adjust resistances by applying signals to the first resistance adjustment circuit 15 and/or the second resistance adjustment circuit 25 using existing pads D1 and/or D2 corresponding to test circuits 41 and 42, so that the reset voltage level may increase or decrease. In this example, the signals input to the pads D1 and D2 may be changed according to subsequent testing to cause the reset signal VCCH to transition to a logic low level. For example, the signals input through the pads D1 and D2 for testing may also be input to the power-up reset circuit, however, the reset signal VCCH may transition to a logic low level when the reset voltage level increases due to the signals, so that the semiconductor device including the power-up reset circuit may operate improperly. Accordingly, power-up reset circuits, according to at least some example embodiments (e.g., a shown in FIG. 5), may have latch 35 disposed in the signal generation circuit 31. The latch 35 may maintain the reset signal VCCH at a logic high level regardless of the reset voltage level after the reset signal VCCH transitions to the logic high level.

For example, in the case of the power-up reset circuit shown in FIG. 5, when the reset voltage level is determined by the signals input through the pads D1 and D2 during a power-up operation and the reset signal VCCH transitions to a logic high level in response to the determined reset voltage level, the reset signal VCCH keeps the logic high level without being affected by subsequent signals input through the pads D1 and D2. Therefore, improper operation of semiconductor devices having power-up reset circuits due to signals input through the pads D1 and D2 after a power-up operation may be suppressed and/or prevented.

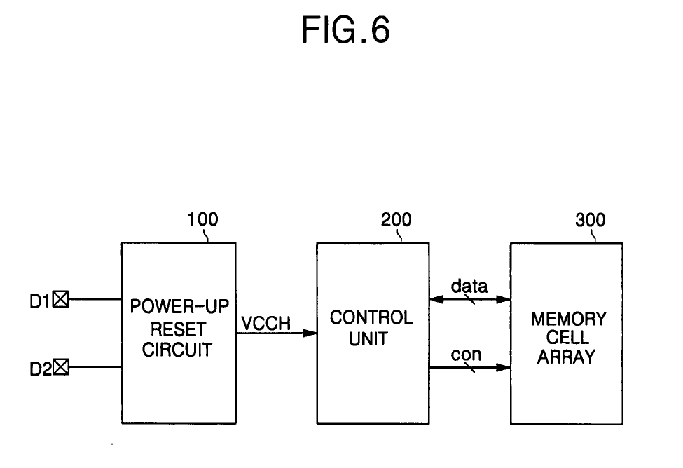

FIG. 6 is a block diagram of a semiconductor device including a power-up reset circuit according to an example embodiment. The semiconductor device shown in FIG. 6 may include a power-up reset circuit 100, a control circuit or unit 200 and/or a memory cell array 300. Referring to FIG. 6, reference symbols D1 and D2 denote pads, and may be disposed in scribe lane regions (not shown) to be cut for separating chips from each other.

Referring to FIG. 6, the power-up reset circuit 100 may output a reset signal VCCH, which may transition to a logic high level when an external power supply voltage reaches a reset voltage level during a power-up operation. As described above, the reset voltage level may be adjusted by the signals input through the pads D1 and D2. The control circuit 200 may output a control signal con to the memory cell array 300 in accordance with read and write operations, and may send and/or receives data signals data. The control circuit 200 may initialize an internal latch or the like in response to the reset signal VCCH input from the power-up reset circuit 100. The memory cell array 300 may store and/or output data in response to the control signal con input from the control circuit 200.

In the case of the semiconductor device shown in FIG. 6, the pads D1 and D2 may be separately disposed for adjusting the reset voltage level, however, the existing pads disposed for the test circuits as described above with reference to FIG. 5 may also be used.

FIG. 6 corresponds to an example case in which an example embodiment is applied to a semiconductor memory device, however, example embodiments may be applied to any semiconductor device having a power-up reset circuit.

According to at least some example embodiments, two resistance adjustment circuits are illustrated in FIGS. 3 to 5, however, the number of the resistance adjustment unit may be one or more (e.g., at least three) if necessary.

For example, the power-up reset circuit and the semiconductor device including the power-up reset circuit according to at least some example embodiments, may not cut fuses during testing at a wafer level, but may apply proper signals to resistance adjustment units through pads to adjust a rest voltage level, so that the test may be performed (e.g., even when problems occur on the reset voltage level due to problems in processing). Fuses may be cut after the test is completed so that the reset voltage level may be adjusted to the same or substantially the same level as the adjusted reset voltage level during testing.

According to at least some example embodiments, in power-up reset circuits and/or semiconductor devices including the same, a reset voltage level may be adjusted by applying proper signals to resistance adjustment units through pads so that test efficiency may be enhanced.

Example embodiments have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A power-up reset circuit, comprising:
a sensing circuit configured to output a node voltage in response to an external power supply voltage;
an output circuit configured to output a voltage sensing signal in response to the node voltage;
a signal generation circuit configured to output a reset signal in response to the voltage sensing signal; and
at least one first resistance adjustment circuit configured to adjust a level of the node voltage in response to an externally input first control signal.

2. The power-up reset circuit according to claim 1, wherein the sensing circuit includes,
a plurality of first resistors serially connected between the external power supply voltage and an output terminal at which the node voltage is output, and
a plurality of second resistors serially connected between the output terminal and a ground voltage.

3. The power-up reset circuit according to claim 2, wherein the at least one first resistance adjustment circuit includes,
a first transistor connected to at least a portion of the first resistors in parallel, the first control signal being applied to a gate of the first transistor.

4. The power-up reset circuit according to claim 1, wherein the output circuit includes,
a pull-up circuit connected between the external power supply voltage and a node from which the voltage sensing signal is output, and
a pull-down circuit connected between the node from which the voltage sensing signal is output and ground and including a pull-down transistor, the node voltage being applied to a gate of the pull-down transistor.

5. The power-up reset circuit according to claim 1, wherein the signal generation circuit includes,
at least one inverter configured to invert the voltage sensing signal to generate the reset signal, the voltage sensing signal being delayed by a first time period.

6. The power-up reset circuit according to claim 4, wherein the output circuit further includes,
a second resistance adjustment circuit configured to adjust a level of the voltage sensing signal in response to an externally input second control signal.

7. The power-up reset circuit according to claim 6, wherein the pull-up circuit includes a plurality of first resistors serially connected between the external power supply voltage and an output terminal at which the voltage sensing signal is output; and
the second resistance adjustment circuit includes
a transistor connected between the external power supply voltage and a node from which the voltage sensing signal is output, the second control signal being applied to a gate of the transistor.

8. The power-up reset circuit according to claim 1, wherein the signal generation circuit further includes,
a latch configured to maintain the reset signal at a first logic level after the reset signal transitions to the first logic level.

9. The power-up reset circuit according to claim 8, wherein the latch further includes,
a NOR gate configured to receive the reset signal as an input and output a signal having a phase opposite to the received reset signal.

10. The power-up reset circuit according to claim 3, further comprising at least one second resistance adjustment circuit,
wherein the at least one second resistance adjustment circuit includes a second transistor connected to at least a portion of the second resistors in parallel, a second control signal being applied to a gate of the second transistor.

11. A semiconductor device, comprising:
a plurality of pads for externally inputting a plurality of test signals; and
a power-up reset circuit, comprising,
a sensing circuit configured to output a node voltage in response to an external power supply voltage;
an output circuit configured to output a voltage sensing signal in response to the node voltage;
a signal generation circuit configured to output a reset signal in response to the voltage sensing signal; and
at least one first resistance adjustment circuit configured to adjust a level of the node voltage in response to a first test signal among the plurality of test signals.

12. The semiconductor device according to claim 11, wherein the sensing circuit includes,
a plurality of first resistors serially connected between the external power supply voltage and an output terminal at which the node voltage is output, and
a plurality of second resistors serially connected between the output terminal and a ground voltage.

13. The semiconductor device according to claim 12, wherein the at least one first resistance adjustment circuit includes,
a first transistor connected to at least a portion of the first resistors in parallel, the first test signal being applied to a gate of the first transistor.

14. The semiconductor device according to claim 11, wherein the output circuit includes,
a pull-up circuit connected between the external power supply voltage and a node from which the voltage sensing signal is output, and
a pull-down circuit connected between the node from which the voltage sensing signal is output and ground and including a pull-down transistor, the node voltage being applied to a gate of the pull-down transistor.

15. The semiconductor device according to claim 11, wherein the signal generation circuit includes,
at least one inverter configured to invert the voltage sensing signal to generate the reset signal, the voltage sensing signal being delayed by a first time period.

16. The semiconductor device according to claim 14, wherein the output circuit further includes,
a second resistance adjustment circuit configured to adjust a level of the voltage sensing signal in response to a second test signal among the plurality of test signals.

17. The semiconductor device according to claim 16, wherein the pull-up circuit includes a plurality of first resistors serially connected between the external power supply voltage and an output terminal at which the voltage sensing signal is output; and
the second resistance adjustment circuit includes a transistor connected between the external power supply voltage and a node from which the voltage sensing signal is output, the second test signal being applied to a gate of the transistor.

18. The semiconductor device according to claim 11, wherein the signal generation circuit further includes,
a latch configured to maintain the reset signal at a first logic level after the reset signal transitions to the first logic level.

19. The semiconductor device according to claim 18, wherein the latch further includes,
a NOR gate configured to receive the reset signal as an input and output a signal having a phase opposite to the received reset signal.

20. The semiconductor device according to claim 13, further comprising at least one second resistance adjustment circuit,
wherein the at least one second resistance adjustment circuit includes a second transistor connected to at least a portion of the second resistors in parallel, a second control signal being applied to a gate of the second transistor.
